(19) United States
(12) Patent Application Publication
(10) Pub. No.: US 2026/0182328 A1
(43) Pub. Date: Jun. 25, 2026

(54) PLASMA TREATMENT FACILITATING SELECTIVE METAL GROWTH AND PREVENTING DIELECTRIC DAMAGE

(71) Applicant: Applied Materials, Inc., Santa Clara, CA (US)

(72) Inventors: Aixi ZHANG, Santa Clara, CA (US); Yi XU, San Jose, CA (US); Hao ZHUANG, Mountain View, CA (US); Jiajie CEN, Santa Clara, CA (US); Zhimin QI, Santa Clara, CA (US); Yu LEI, Belmont, CA (US); Rongjun WANG, Dublin, CA (US)

(21) Appl. No.: 18/987,976

(22) Filed: Dec. 19, 2024

(51) Int. Cl. H01L 21/768; H01J 37/32; H01L 21/285

(52) U.S. Cl. CPC H10W 20/076; H10P 14/42; H10W 20/056; H01J 37/32357; H01J 2237/3321

(57) ABSTRACT

Embodiments of the disclosure include a method of depositing a gap-fill material on a semiconductor substrate, comprising: forming a passivation layer on a surface of a contact structure by introducing a hydrogen gas and an oxygen gas and/or water from a remote plasma source to a processing chamber, and depositing a metal gap-fill material over a portion of the passivation layer to fill the feature formed in the surface of the semiconductor substrate. The contact structure includes a feature formed in a surface of the semiconductor substrate. The feature comprises an opening that is defined by a substrate, a lower dielectric material disposed over the substrate, and an upper dielectric material disposed over the lower dielectric material, and the passivation layer is formed over the substrate, the lower dielectric material, and the upper dielectric material.

### BACKGROUND

### Field

Embodiments of the present invention generally relate to systems and methods used in electronic device manufacturing, and more particularly, to systems and methods used for forming tungsten or molybdenum features in a semiconductor device.

### Description of the Related Art

Gap-fill materials, e.g., tungsten (W) and/or molybdenum (Mo), are widely used in integrated circuit (IC) device manufacturing to form conductive features where relatively low electrical resistance and relativity high resistance to electromigration are desired. For example, gap-fill materials may be used to form source contacts, drain contacts, metal gate fill, gate contacts, interconnects (e.g., horizontal features formed in a surface of a dielectric material layer), and vias (e.g., vertical features formed through a dielectric material layer to connect other interconnect features disposed there above and there below).

Due to a relativity low resistivity, gap-fill materials are also commonly used to form bit lines and word lines used to address individual memory cells in a memory cell array of a three-dimensional NAND (3D NAND) device. 3D NAND structures include tiers of horizontal arrays that can be stacked by depositing layers in sequence. Channels can be formed through the stack of films and filled with gap-fill materials. In some cases, the channel sidewall widths can vary between tiers. Moreover, residual silica bonds can be exposed during the processing, causing undesired nucleation and growth during gap fill processes due to the increased reactivity between the gap-fill material and the residual silica bonds. Subsequently, during filling the channel, the gap-fill material can deposit an upper portion of the channel quicker than a lower portion due to the varying channel sidewall widths and higher concentration of precursor gases used to deposit the gap-fill material. This can cause void formation within portions of the channels, particular for channels disposed in structures having two or more tiers, and particular for high aspect ratio features.

Accordingly, there is a need for processes to fill contact features that are free or substantially free of voids and seams and have low resistivity for various film thicknesses within channels.

### SUMMARY

Embodiments of the disclosure include a method of depositing a gap-fill material on a semiconductor substrate, comprising forming a passivation layer on a surface of a contact structure by introducing a hydrogen gas and an oxygen gas from a remote plasma source to a processing chamber, wherein the contact structure comprises a feature formed in a surface of the semiconductor substrate, the feature comprises an opening that is defined by a substrate, a lower dielectric material disposed over the substrate, and an upper dielectric material disposed over the lower dielectric material, and the passivation layer is formed over the substrate, the lower dielectric material, and the upper dielectric material. Then depositing a metal gap-fill material over a portion of the passivation layer to fill the feature formed in the surface of the semiconductor substrate.

Embodiments of the disclosure further include a method of depositing a gap-fill material on a semiconductor substrate, comprising performing a preclean process on a surface of a contact structure; and forming a passivation layer on the surface of the contact structure by introducing a first gas comprising hydrogen gas or an oxygen gas and a second gas comprising water from a remote plasma source to a processing chamber, wherein the contact structure comprises a feature formed in a surface of the semiconductor substrate, the feature comprises an opening that is defined by a substrate, a lower dielectric material disposed over the substrate, and an upper dielectric material disposed over the lower dielectric material, and the passivation layer is formed over the substrate, the lower dielectric material, and the upper dielectric material. Then depositing a metal gap-fill material over a portion of the passivation layer to fill the feature formed in the surface of the semiconductor substrate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A is a schematic side view of a processing system that may be used to implement the methods set forth herein, according to embodiments of the present disclosure.

FIG. 1B is a close-up sectional view of a portion of the processing system shown in FIG. 1A, according to embodiments of the present disclosure.

FIG. 2 is a diagram illustrating a substrate processing method, according to one embodiment, which may be performed using the processing system of FIGS. 1A-1B, according to embodiments of the present disclosure.

FIGS. 3A-3C are schematic sectional views of a portion of a substrate illustrating various aspects of the method set forth in FIG. 2, according to embodiments of the present disclosure.

FIG. 4 illustrates a schematic plan view of a cluster tool according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments herein are generally directed electronic device manufacturing and, more particularly, to systems and methods for forming low resistivity features in a contact structure of a semiconductor device manufacturing scheme.

Typically, the features in an integrated circuit (IC) device are formed using a damascene (metal inlay) manufacturing process flow. The damascene process flow begins with depositing a layer of dielectric material on the surface of the substrate, patterning the dielectric layer to form a plurality of openings, and depositing a passivation layer onto the surface of the dielectric layer and prevent oxidation of the metal layer. For example, a passivation layer including a barrier layer or adhesion material is formed, thereby lining the openings before deposition of the gap-fill material.

Typically, passivation layers formed using conventional methods are highly non-conformal decaying from the top to the bottom of the opening. However, as device features shrink and aspect ratios increase, the formation of undesirable voids and seams in gap-fill features formed using conventional methods is largely unavoidable, due to the varying channel sidewall widths, damage from process and higher concentration of precursor gases used to deposit the gap-fill material along top portions of the high aspect ratio features. For example, using the conventional passivation method often leads to the growth of a tapered surface and/or angled surface during a subsequent conventional gap-fill processes due to the higher concentrations of gap-fill precursor gases (e.g., metal containing precursor gases) forming the gap-fill layer, in which the gap-fill layer preferentially adheres to a top portion of the dielectric material. The resulting undesirable voids and seams may cause device performance and reliability problems or even device failure.

As discussed below, the use of assigned plasma sources for passivation layer deposition processes provides improved processing stability for the passivation treatments when compared to a processing system using a common plasma source for passivation layer formation. Thus, embodiments herein beneficially provide a relativity low-cost and high throughput, solution for conformal passivation layer formation, thereby reducing seams in the gap-fill material.

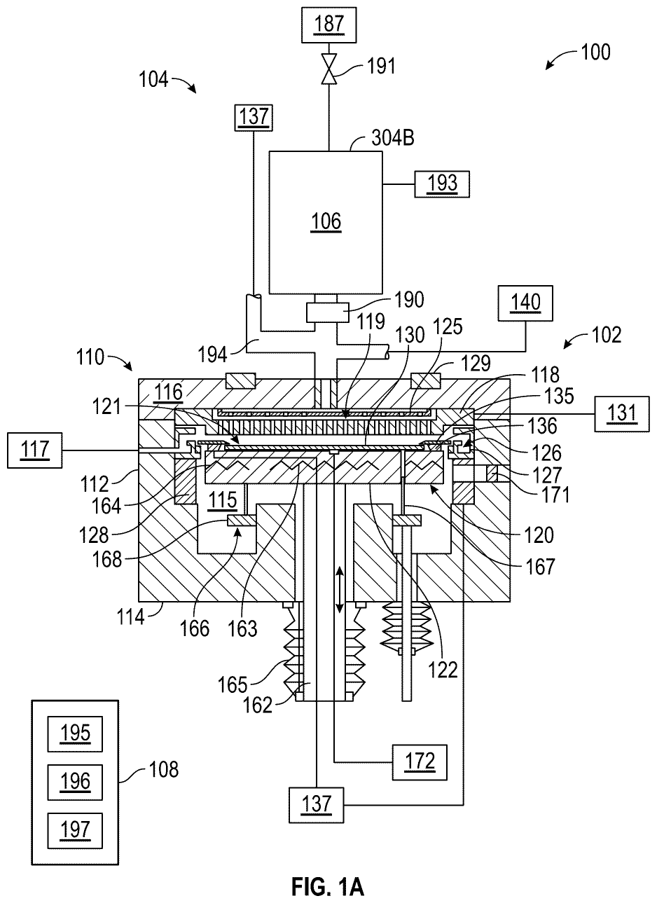

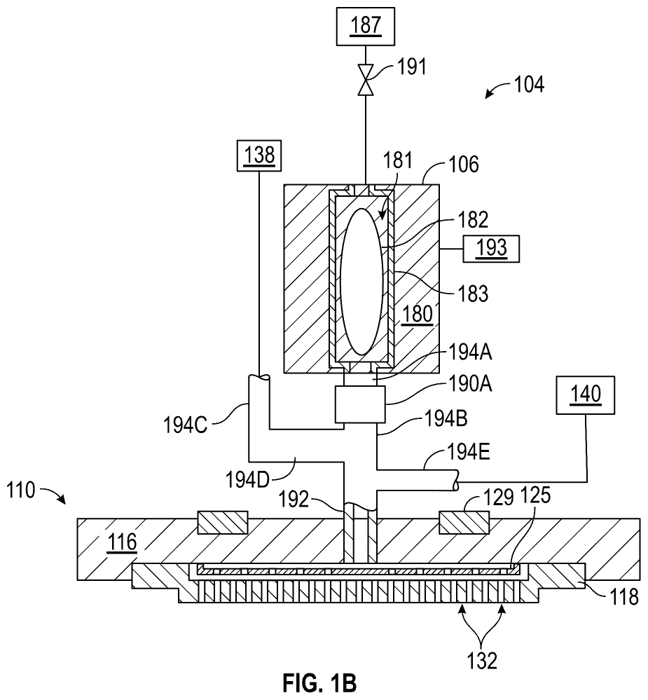

FIGS. 1A-1B schematically illustrate a processing system 100 that may be used to perform the bottom-up gap-fill substrate processing methods described herein. Here, the processing system is configured to provide the different processing conditions desired for each of a preclean process, passivation layer formation process, and selective gap-fill process.

As shown in FIG. 1A, the processing system 100 includes the processing chamber 102, a gas delivery system 104 fluidly coupled to the processing chamber 102, and a system controller 108. The processing chamber 102 (shown in cross-section in FIG. 1A) includes a chamber lid assembly 110, one or more sidewalls 112, and a chamber base 114, which collectively define a processing volume 115. The processing volume 115 is fluidly coupled to an exhaust 117, such as one or more vacuum pumps, used to maintain the processing volume 115 at sub-atmospheric conditions and to evacuate processing gases and processing by-products therefrom.

The chamber lid assembly 110 includes a lid plate 116 and a showerhead 118 coupled to the lid plate 116 to define a gas distribution volume 119 therewith. Here, the lid plate 116 is maintained at a desired temperature using one or more heaters 129 thermally coupled thereto. The showerhead 118 faces a substrate support assembly 120 disposed in the processing volume 115. As discussed below, the substrate support assembly 120 is configured to move a substrate support 122, and thus a substrate 130 disposed on the substrate support 122, between a raised substrate processing position (as shown) and a lowered substrate transfer position (not shown). When the substrate support assembly 120 is in the raised substrate processing position, the showerhead 118 and the substrate support 122 define a processing region 121.

Here, the gas delivery system 104 is fluidly coupled to the processing chamber 102 through a gas inlet (FIG. 1B) that is disposed through the lid plate 116. Processing or cleaning gases delivered, by use of the gas delivery system 104, flow through the gas inlet into the gas distribution volume 119 and are distributed into the processing region 121 through a plurality of openings 132 (FIG. 1B) in the showerhead 118. In some embodiments, the chamber lid assembly 110 further includes a perforated blocker plate 125 disposed between the gas inlet and the showerhead 118. In those embodiments, gases flowed into the gas distribution volume 119 are first diffused by the blocker plate 125 to, together with the showerhead 118, provide a more uniform or desired distribution of gas flow into the processing region 121.

Here, processing gases and processing by-products are evacuated radially outward from the processing region 121 through an annular channel 126 that surrounds the processing region 121. The annular channel 126 may be formed in a first annular liner 127 disposed radially inward of the one or more sidewalls 112 (as shown) or may be formed in the one or more sidewalls 112. In some embodiments, the processing chamber 102 includes one or more second liners 128, which are used to protect the interior surfaces of the one or more sidewalls 112 or chamber base 114 from corrosive gases or undesired material deposition.

In some embodiments, a purge gas source 137 that is in fluid communication with the processing volume 115 is used to flow a chemically inert purge gas, such as argon (Ar), into a region disposed beneath the substrate support 122, e.g., through the opening in the chamber base 114 surrounding a support shaft 162. The purge gas may be used to create a region of positive pressure below the substrate support 122 (when compared to the pressure in the processing region 121) during substrate processing. Typically, purge gas introduced through the chamber base 114 flows upwardly therefrom and around the edges of the substrate support 122 to be evacuated from the processing volume 115 through the annular channel 126. The purge gas reduces undesirable material deposition on surfaces beneath the substrate support 122 by reducing or preventing the flow of material precursor gases thereinto.

Here, the substrate support assembly 120 includes the movable support shaft 162 that sealingly extends through the chamber base 114, such as being surrounded by a bellows 165 in the region below the chamber base 114, and the substrate support 122, which is disposed on the movable support shaft 162. To facilitate substrate transfer to and from the substrate support 122, the substrate support assembly 120 includes a lift pin assembly 166 comprising a plurality of lift pins 167 coupled to or disposed in engagement with a lift pin hoop 168. The plurality of lift pins 167 are movably disposed in openings formed through the substrate support 122. When the substrate support 122 is disposed in a lowered substrate transfer position (not shown), the plurality of lift pins 167 extend above a substrate receiving surface of the substrate support 122 to lift a substrate 130 therefrom and provide access to a backside (non-active) surface of the substrate 130 by a substrate handler (not shown). When the substrate support 122 is in a raised or processing position (as shown), the plurality of lift pins 167 recede beneath the substrate receiving surface of the substrate support 122 to allow the substrate 130 to rest thereon.

Here, the substrate 130 is transferred to and from the substrate support 122 through a door 171, e.g., a slit valve disposed in one of the one or more sidewalls 112. Here, one or more openings in a region surrounding the door 171, e.g., openings in a door housing, are fluidly coupled to a purge gas source 137, e.g., an Ar gas source. The purge gas is used to prevent processing and cleaning gases from contacting or degrading a seal surrounding the door, thus extending the useful lifetime thereof.

Here, the substrate support 122 is configured for vacuum chucking where the substrate 130 is secured to the substrate support 122 by applying a vacuum to an interface between the substrate 130 and the substrate receiving surface. The vacuum is applied by use of a vacuum source 172 fluidly coupled to one or more channels or ports formed in the substrate receiving surface of the substrate support 122. In other embodiments, the processing chamber 102 is configured for remote direct plasma processing, in which the substrate support 122 may be configured for electrostatic chucking. In some embodiments, the substrate support 122 includes one or more electrodes (not shown) coupled to a bias voltage power supply (not shown), such as a continuous wave (CW) RF power supply or a pulsed RF power supply, which supplies a bias voltage thereto.

As shown, the substrate support assembly 120 features a dual-zone temperature control system to provide independent temperature control within different regions of the substrate support 122. The different temperature-controlled regions of the substrate support 122 correspond to different regions of the substrate 130 disposed thereon. Here, the temperature control system includes a first heater 163 and a second heater 164. The first heater 163 is disposed in a central region of the substrate support 122, and the second heater 164 is disposed radially outward from the central region to surround the first heater 163. In other embodiments, the substrate support 122 may have a single heater or more than two heaters.

In some embodiments, the substrate support assembly 120 optionally further includes an annular shadow ring 135, which is used to prevent undesired material deposition on a circumferential bevel edge of the substrate 130. During substrate transfer to and from the substrate support 122, i.e., when the substrate support assembly 120 is disposed in a lowered position (not shown), the shadow ring 135 rests on an annular ledge within the processing volume 115. When the substrate support assembly 120 is disposed in a raised or processing position, the radially outward surface of the substrate support 122 engages with the annular shadow ring 135 so that the shadow ring 135 circumscribes the substrate 130 disposed on the substrate support 122. Here, the shadow ring 135 is shaped so that a radially inward facing portion of the shadow ring 135 is disposed above the bevel edge of the substrate 130 when the substrate support assembly 120 is in the raised substrate processing position.

In some embodiments, the substrate support assembly 120 further includes an annular purge ring 136 disposed on the substrate support 122 to circumscribe the substrate 130. In those embodiments, the shadow ring 135 may be disposed on the purge ring 136 when the substrate support assembly 120 is in the raised substrate processing position. Typically, the purge ring 136 features a plurality of radially inward facing openings that are in fluid communication with the purge gas source 137. During substrate processing, a purge gas flows into an annular region defined by the shadow ring 135, the purge ring 136, the substrate support 122, and the bevel edge of the substrate 130 to prevent processing gases from entering the annular region and causing undesired material deposition on the bevel edge of the substrate 130.

In some embodiments, the processing chamber 102 is configured for remote direct plasma processing. In those embodiments, the showerhead 118 may be electrically coupled to a first power supply 131, such as an RF power supply, which supplies power to ignite and maintain a plasma of processing gases flowed into the processing region 121 through capacitive coupling therewith. In some embodiments, the processing chamber 102 comprises an inductive plasma generator (not shown), and a plasma is formed through inductively coupling an RF power to the processing gas.

Here, the processing system 100 is advantageously configured to perform each of the precleaning processes, passivation layer formation processes, and gap-fill deposition processes in the processing chamber 102. The gases used to perform the individual processes of the gap-fill process scheme, and to clean residues from the interior surfaces of the processing chamber, are delivered to the processing chamber 102 using the gas delivery system 104 fluidly coupled thereto.

The gas delivery system 104 includes a remote plasma source, shown as the radical generator 106, a deposition gas source 140, and a conduit system 194 (e.g., the plurality of conduits 194A-E in FIG. 1B) fluidly coupling the radical generator 106 and the deposition gas source 140 to the lid assembly 110. While FIG. 1B shows one remote plasma source, the gas delivery system 104 can include a dual remote plasma source and/or a plurality of remote plasma sources. The gas delivery system 104 further includes an isolation valve, here the isolation valve 190, disposed between the radical generator 106 and the lid plate 116, which may be used to fluidly isolate each of the radical generator 106 from the processing chamber 102 and from one another.

Here, the radical generator 106 features a chamber body 180 that defines the plasma chamber volume 181 (FIG. 1B). The radical generator 106 is coupled to a power supply 193. The power supplies 193 are used to ignite and maintain a plasma 182 of gases delivered to the plasma chamber volumes 181 from a gas source 187 fluidly coupled thereto. For example, the radical generator 106 may be used to ignite and maintain a treatment plasma 182 from a non-halogen-containing gas mixture thereof delivered to the plasma chamber volume 181 from the gas source 187. The gas source 187 may provide a hydrogen containing gas mixture, such as H₂ and/or H₂O, mixed with a carrier gas, such as Ar, to the radical generator 106, and an oxygen-containing gas, such as O₂ and/or H₂O, mixed with a carrier gas, such as Ar, to the radical generator 106.

Suitable remote plasma sources which may be used for the radical generator 106 include radio frequency (RF) or very high radio frequency (VHRF) capacitively coupled plasma (CCP) sources, inductively coupled plasma (ICP) sources, microwave-induced (MW) plasma sources, electron cyclotron resonance (ECR) chambers, or high-density plasma (HDP) chambers.

As shown, the radical generator 106 is fluidly coupled to the processing chamber 102 by use of first and second conduit 194A-B, which extend upwardly from the gas inlet to connect with an outlet of the plasma chamber volume 181. A valve 190, disposed between the first and second conduits 194A-B, is used to selectively fluidly isolate the radical generator 106 from the processing chamber 102 and the other portions of the gas delivery system 104.

In some embodiments, the plasma-facing surfaces 183 of the plasma chamber volume 181 is formed of a halogen-based plasma resistant material, such as aluminum oxide, aluminum nitride, silicon oxide, fused silica, quartz, sapphire, or combinations thereof. In some embodiments, the plasma-facing surfaces 183 of the plasma chamber volume 181 comprises a tube or a liner formed of the halogen-plasma resistant material. In other embodiments, the plasma-facing surfaces 183 feature a coating or layer of a halogen-based plasma resistant material formed on the interior portions of the chamber body 180, such as an anodized aluminum layer formed on the interior portions of an aluminum chamber body. In some embodiments, one or more of the conduits 194A-D are lined with a low recombination dielectric material 192, such as fused silica, quartz, or sapphire, which desirably reduces recombination of the activated species in the remote plasma effluents as they are delivered to the processing chamber 102.

Here, deposition gases, e.g., tungsten-containing precursors, molybdenum-containing precursors, and reducing agents, can be delivered from the deposition gas source 140 to the processing chamber 102 using a fifth conduit 194E. As shown, the fifth conduit 194E is coupled to the second conduit 194B at a location proximate to the gas inlet so that the valve 190 may be used to respectively isolate the radical generators 106 from deposition gases introduced into the processing chamber 102.

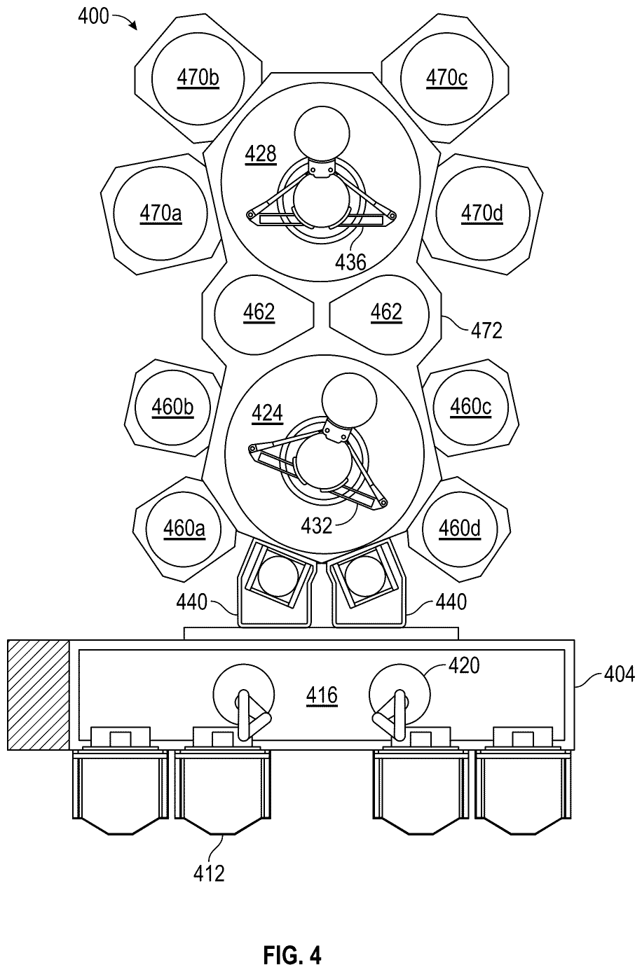

Operation of the processing system 100 is facilitated by the system controller 108. The system controller 108 includes a programmable central processing unit, here a CPU 195, which is operable with a memory 196 (e.g., non-volatile memory) and support circuits 197. The CPU 195 is one of any form of general-purpose computer processor used in an industrial setting, such as a programmable logic controller (PLC), for controlling various chamber components and sub-processors. The memory 196, coupled to the CPU 195, facilitates the operation of the processing chamber. The support circuits 197 are conventionally coupled to the CPU 195 and comprise cache, clock circuits, input/output subsystems, power supplies, and the like, and combinations thereof coupled to the various components of the processing system 100 (or the multi-chamber processing system 400 of FIG. 4) to facilitate control of substrate processing operations therewith.

Here, the instructions in memory 196 are in the form of a program product, such as a program that implements the methods of the present disclosure. In one example, the disclosure may be implemented as a program product stored on computer-readable storage media for use with a computer system. The program(s) of the program product define functions of the embodiments (including the methods described herein). Thus, the computer-readable storage media, when carrying computer-readable instructions that direct the functions of the methods described herein, are embodiments of the present disclosure.

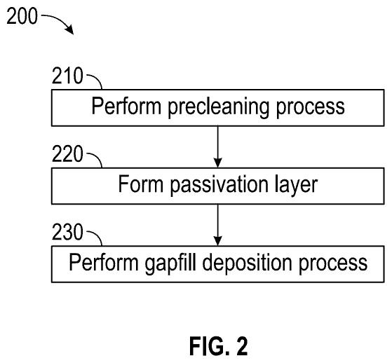

Advantageously, the processing system 100 described above may be used to perform each of the precleaning processes, passivation layer formation, and gap-fill deposition processes of the method 200 set forth in FIG. 2.

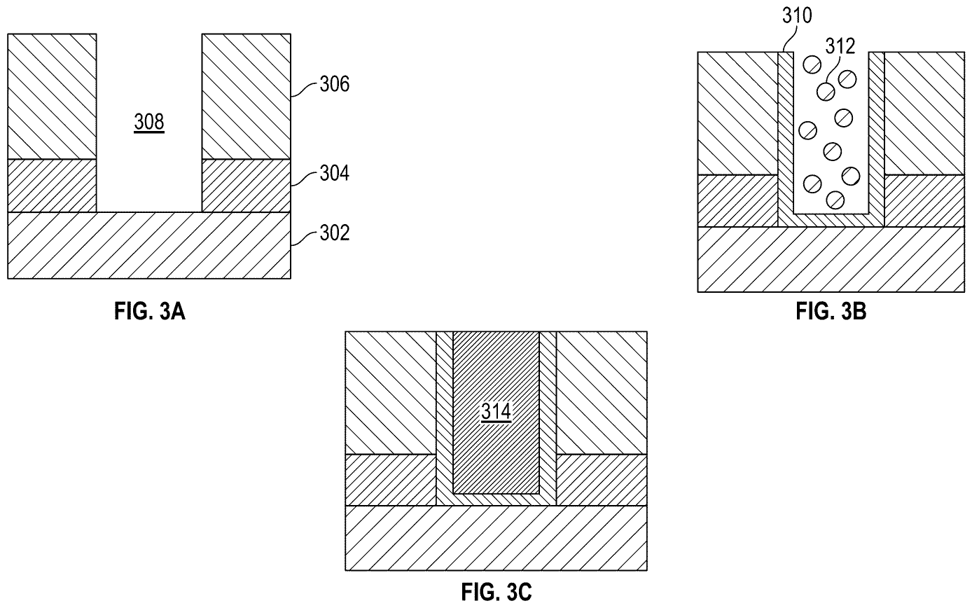

Processes of the present disclosure can provide deposition of conformal passivation layers, to eliminate and/or reduce undesirable voids and seams from being formed in a subsequently formed gap-fill layer, thereby improving device performance and reliability of the formed semiconductor device. The methods of the present disclosure also provide a relativity low-cost and high throughput, solution for conformal passivation layer formation, thereby reducing seams in the subsequently formed gap-fill layer. In the method 200 of FIG. 2, a conformal passivation layer deposition process flow is shown. In the discussion of the method 200, references will be made to FIGS. 3A-3C.

At operation 210, a preclean process is performed to remove any contaminates and/or oxidation from surfaces of a substrate 302, lower dielectric material 304, and/or upper dielectric material 306, as depicted in FIG. 3A. The substrate 302 can include an interconnect metal layer including a metal material, such as a metal material including cobalt (Co), molybdenum (Mo), tungsten (W), tantalum (Ta), titanium (Ti), ruthenium (Ru), rhodium (Rh), copper (Cu), iron (Fe), manganese (Mn), vanadium (V), niobium (Nb), hafnium (Hf), zirconium (Zr), yttrium (Y), aluminum (AI), tin (Sn), chromium (Cr), lanthanum (La), iridium (Ir), or combinations thereof. In some embodiments, the substrate 302 includes one or more layers that include a metal layer disposed within a dielectric layer that is disposed over a semiconductor material layer or substrate.

The lower dielectric material 304 is disposed over the substrate. The lower dielectric material 304 is formed from a dielectric material (e.g., silicon dioxide, silicon nitride, etc.), and can form part of an etch stop layer. In some embodiments, the lower dielectric material 304 may be a silicon material or a silicon germanium (SiGe) material. For example, the lower dielectric material 304 can be formed from a silicon nitride. The upper dielectric material 306 is disposed over the lower dielectric material 304. The upper dielectric material 306 is formed from a dielectric material that is different than the lower dielectric material 304 (e.g., silicon dioxide, silicon nitride, etc.). In some embodiments, the upper dielectric material 306 may be a silicon material or a silicon germanium (SiGe) material. For example, the upper dielectric material 306 can be formed from a silicon oxide. In some embodiments, the feature can include a multilayer stack of interleaved materials, such as a multilayer stack that include a repeating set of lower dielectric material 304 layers and upper dielectric material 306 layers.

Here, the lower dielectric material 304 and the upper dielectric material 306 are patterned to produce a plurality of openings 308 (one shown) formed therein. In some embodiments, the plurality of openings 308 comprises one or a combination of high aspect ratio via or trench openings having a width of about 1 μm or less, such as about 800 nm or less, or about 500 nm or less, and a depth of about 2 μm or more, such as about 3 μm or more, or about 4 μm or more. In some embodiments, individual openings of the plurality of openings 308 may have an aspect ratio (depth to width ratio) of about 5:1 or more, such as about 10:1 or more, 15:1 or more, or between about 10:1 and about 100:1, such as between about 15:1 and about 100:1.

At operation 220, the method 200 includes forming a passivation layer 310 over the substrate 302, lower dielectric material 304, and/or upper dielectric material 306 to inhibit oxidation of the substrate 302, lower dielectric material 304, and/or upper dielectric material 306. Forming the passivation layer 310 includes exposing the substrate 302, lower dielectric material 304, and/or upper dielectric material 306 to an activated species of a treatment gas, e.g., treatment radicals 312 shown in FIG. 3B. In some embodiments, exposing the substrate 302, lower dielectric material 304, and/or upper dielectric material 306 to the treatment radicals 312 includes forming a treatment plasma 182A of a substantially first gas mixture (e.g., a hydrogen containing gas) and a second gas mixture (e.g., an oxygen containing gas) using a remote plasma source, e.g., the first radical generator 106A and/or the second radical generator 106B, and flowing the effluent of the treatment plasma 182A and/or 182B into the processing region 121.

In some embodiments, the first treatment gas may include hydrogen, water, or combinations thereof. In some embodiments, the second treatment gas comprises oxygen, water, or a combination thereof, and the activated species comprise hydrogen radicals and/or oxygen radicals. In one example, the activated species of a treatment gas includes a first treatment gas that includes hydrogen (H₂) and second treatment gas that includes oxygen (O₂). In some embodiments, the first treatment gas is combined with an inert carrier gas, such as Ar, He, or a combination thereof, to form a first treatment gas mixture. In some embodiments, the second treatment gas is combined with an inert gas, e.g., Ar, to form a second treatment gas mixture. In some embodiments, a concentration of the first treatment gas in the first treatment gas mixture is between about 0.1 vol. % and about 50 vol. %, such as between about 0.5 vol. % and about 40 vol. %, between about 0.5 vol. % and about 30 vol. %, about 0.5 vol. % and about 20 vol. %, or, for example, between about 0.5 vol. % and about 10 vol. %, such as between about 0.5 vol. % and about 5 vol. %.

In some embodiments, the first treatment gas and the second treatment gas may be mixed to produce a ratio of the hydrogen-containing gas and the oxygen-containing gas. The ratio of the hydrogen-containing gas and the oxygen-containing gas can include a ratio of about 1 vol. % to about 100 vol. % of the hydrogen-containing gas and the oxygen-containing gas. For example, the ratio of the hydrogen-containing gas and the oxygen-containing gas can include a ratio of about 1 vol. % to about 90 vol. % of the hydrogen-containing gas and the oxygen-containing gas. In some embodiments, where the hydrogen-containing gas is hydrogen, and the oxygen-containing has is oxygen, the ratio of the hydrogen-containing gas and the oxygen-containing gas can be about 1 vol. % to about 90 vol. %. In some embodiments, where the hydrogen-containing gas is hydrogen, and the oxygen-containing gas is water, the ratio of the hydrogen-containing gas and the oxygen-containing gas can be about 1 vol. % to about 100 vol. %.

In some embodiments, a flow rate of the first treatment gas mixture into the first radical generator 106A is between about 1 sccm and about 7000 sccm, such as between about 1 sccm and about 6500 sccm, between about 1 sccm and about 6000 sccm, between about 1 sccm and about 4000 sccm, between about 1 sccm and about 3000 sccm, between about 1 sccm and about 2500 sccm between about 1 sccm and about 1000 sccm, or between about 1 sccm and about 750 sccm, for example, between about 1 sccm and about 50 sccm. In some embodiments the flow rate of the second treatment gas mixture into the second radical generator 106B is between about 1 sccm and about 7000 sccm, such as between about 1 sccm and about 6500 sccm, between about 1 sccm and about 6000 sccm, between about 1 sccm and about 4000 sccm, between about 1 sccm and about 3000 sccm, between about 1 sccm and about 2500 sccm between about 1 sccm and about 1000 sccm, or between about 1 sccm and about 750 sccm, for example, between about 1 sccm and about 50 sccm. In some embodiments, the first radical generator 106A and/or the second radical generator may be operated at a power of about 2 KW to about 8 KW, e.g., about 2 KW to about 7.5 KW, about 3 KW to about 7 KW, or about 4 KW to about 6 kW.

In other embodiments, the treatment radicals 312, e.g., hydrogen radicals, oxygen radicals, and/or hydroxide radicals, may be formed using a remote plasma source and/or a remote direct plasma (not shown). The remote direct plasma (not shown) is ignited and maintained in a portion of the processing volume 115 that is separated from the processing region 121 by the showerhead 118, such as between the showerhead 118 and the lid plate 116. Additionally, or alternatively, treatment radicals 312 may be formed in the plasma 182A-B of the plasma chamber volumes 181A-B. The treatment radicals 312 may then be introduced to the processing volume 115 and/or processing region 121 via the showerhead 118. The use of a remote plasma source (e.g., first radical generator 106A and/or second radical generator 106B) and the remote direct plasma for the passivation layer deposition process at operation 220 desirably provides for improved conformality of the passivation layer in high aspect ratio cavities compared to conventional direct plasma sources for passivation layer deposition processes. This is likely because a remote plasma source introduces substantially less ions and more radicals, thereby reducing ion-based damage to the substrate 302, lower dielectric material 304, and/or upper dielectric material 306.

In these embodiments, the activated treatment gas (i.e., treatment gas comprising the first treatment gas, the second treatment gas, and/or the inert gas) may be flowed through an ion filter to remove substantially all ions therefrom before the treatment radicals 312 reach the processing region 121 and the surface of the substrate 302, lower dielectric material 304, and/or upper dielectric material 306, thereby reducing ion-base damage to the substrate 302, lower dielectric material 304, and/or upper dielectric material 306, and improving conformality of the formed passivation layer. In some embodiments, the flow rate of the activated treatment gas can be about 100 sccm to about 15 slm. In some embodiments, the showerhead 118 may be used as the ion filter due to it being grounded and its position downstream of the plasma generating sources. In other embodiments, a plasma used to form the treatment radicals is an in-situ plasma (or non-remote direct plasma) formed in the processing region 121 between the showerhead 118 and the substrate 302, lower dielectric material 304, and/or upper dielectric material 306. In some embodiments, e.g., when using an in-situ treatment plasma, the substrate 302 may be biased to control the directionality and/or accelerate ions formed from the treatment gas, e.g., charged treatment radicals, towards the substrate surface. In some embodiments, the plasma density of the plasma can be about 1×10¹⁰ to about 1×10¹⁴/cm³

Without intending to be bound by theory, it is believed that the activated hydrogen species and/or oxygen species (from treatment radicals 312) are incorporated into portions of the substrate 302, the lower dielectric material 304, and/or the upper dielectric material 306 by adsorption of the activated species and/or by reaction with the substrate 302, the lower dielectric material 304, and/or the upper dielectric material 306. The adsorbed hydrogen and/or oxygen of the substrate 302, the lower dielectric material 304, and/or the upper dielectric material 306 desirably delays (inhibits) further oxidation of the substrate 302, the lower dielectric material 304, and/or the upper dielectric material 306.

In some embodiments, the passivation layer deposition process includes exposing the substrate 302 to the treatment radicals 312 for a period of about 5 seconds or more, such as about 6 seconds or more, about 7 seconds or more, about 8 seconds or more, about 9 seconds or more, about 10 second or more, or between about 5 seconds and about 600 seconds, such as between about 5 seconds and about 90 seconds, or between about 5 seconds and about 60 seconds, or between about 5 seconds and about 30 seconds, for example, between about 5 seconds and about 20 seconds.

In some embodiments, the passivation layer deposition process includes maintaining the processing volume 115 at a pressure of less than about 10 Torr while flowing the activated treatment gas thereinto. For example, during the passivation layer deposition process, the processing volume 115 may be maintained at a pressure of less than about 7.5 Torr, such as less than about 5 Torr, less than about 1.5 Torr, less than about 1 Torr, or between about 0.5 Torr and about 10 Torr, such as between about 0.5 Torr and about 8 Torr, or between about 0.5 Torr and about 5 Torr, or for example, between about 0.5 Torr and about 1 Torr.

In some embodiments, the passivation layer deposition process includes forming a passivation layer 310 having a thickness of about 10 Å to about 20 Å, e.g., about 10 Å to about 18 Å, about 12 Å to about 17 Å, or about 14 Å to about 17 Å. Without being bound by theory, the passivation layer 310 can include a substantially conformal layer, in which the passivation layer 310 disposed over the upper dielectric material 306 includes a thickness of about 14 Å to about 17 Å, the passivation layer 310 disposed over the lower dielectric material 304 includes a thickness of about 14 Å to about 17 Å, and the passivation layer 310 disposed over the substrate 302 includes a thickness of about 14 Å to about 17 Å.

At operation 230, the method 200 includes depositing a gap-fill material 314 (FIG. 3C) into the plurality of openings 308. In one embodiment, the gap-fill material 314 is formed using a low-stress chemical vapor deposition (CVD) process comprising concurrently flowing (co-flowing) a metal-containing precursor gas, e.g., tungsten-containing precursor gas, molybdenum-containing precursor gas, and/or titanium-containing precursor gas, and a reducing agent into the processing region 121 and exposing the substrate 302 thereto. The metal-containing precursor and the reducing agent used for the gap-fill CVD process may comprise any combination of the metal-containing precursors and reducing agents described herein. In some embodiments, the metal-containing precursor comprises WF₆, and the reducing agent comprises H₂. Without being bound by theory, the passivation layer formed using the treatment radical includes increased conformality, thereby reducing a tapered profile of the passivation layer formed over the dielectric surface. Furthermore, and without being bound by theory, the increased conformality allows for a reduction in the formation of seams during the gap-fill processes described herein due to the substantially similar volumes of a top portion and a bottom portion of the cavity.

Here, the metal-containing precursor is flowed into the processing region 121 at a rate of between about 0.1 sccm and about 7000 sccm, e.g., between about 10 sccm and about 6000 sccm. The reducing agent is flowed into the processing region 121 at a rate of between about 500 sccm and about 10000 sccm, such as between about 1000 sccm and about 9000 sccm, or between about 1000 sccm and about 8000 sccm.

In some embodiments, the gap-fill CVD process conditions are selected to provide a gap-fill material having a relativity low residual film stress when compared to conventional gap-fill CVD processes. For example, in some embodiments, the gap-fill CVD process includes heating the substrate to a temperature of about 70° C. to about 500° C., such as between about 200° C. and about 500° C. During the CVD process, the processing volume 115 is typically maintained at a pressure of less than about 10 Torr, such as less than about 7.5 Torr, such as less than about 5 Torr, less than about 1.5 Torr, less than about 1 Torr, or between about 0.5 Torr and about 10 Torr, such as between about 0.5 Torr and about 8 Torr, or between about 0.5 Torr and about 5 Torr, or for example, between about 0.5 Torr and about 1 Torr.

In other embodiments, the gap-fill material 314 is deposited using a pulsed CVD method that includes repeating cycles of alternately exposing the substrate 302 to a metal-containing precursor gas and a reducing agent without purging the processing region 121. The processing conditions for the gap-fill pulsed CVD method may be the same, substantially the same, or within the same ranges as those described above for the CVD process.

In a typical semiconductor manufacturing scheme, a chemical mechanical polishing (CMP) process may be used to remove an overburden of gap-fill material from the field surface of the substrate following depositing the gap-fill material 314 into the opening 308. CMP processes generally rely on a combination of chemical and mechanical activity to facilitate uniform removal of the overburden layer and an endpoint detection method to determine when the gap-fill overburden has cleared from the field surface. Non-uniform clearing of gap-fill from the field surface or failure to detect a polishing endpoint can result in undesired over-polishing or under-polishing of at least some regions of the substrate surface. Gap-fill over-polishing can cause undesired removal of gap-fill from the feature, e.g., feature coring, because the polishing fluid in a CMP process is often corrosive and can cause damage to the features during over-polishing. Gap-fill under-polishing can result in undesired residual gap-fill remaining on the field surface following CMP.

In some embodiments, the methods described above may be performed using a multi-chamber processing system 400, such as illustrated in FIG. 4. FIG. 4 is a schematic plan view of a cluster tool 400. One example of the cluster tool 400 is the Endura® system from Applied Materials, Inc. of Santa Clara, California. It is understood that the cluster tool 400 described below is an exemplary cluster tool and other cluster tools, including those from other manufacturers, may be used with or modified to form passivation layers as described herein.

The cluster tool 400 includes a factory interface 404, loading dock 440, first transfer chamber 424, and second transfer chamber 428. A plurality of cassettes 412, or front opening unified pods (“FOUPs”), are disposed on the factory interface 404 and are configured to receive a plurality of patterned device structures for processing. Prior to processing, the patterned device structures are removed from the cassettes 412 by factory interface robots 420 and are transferred to the loading dock 440 (i.e., load lock). Upon completion of substrate processing in the cluster tool 400, the processed patterned device structures may be returned to their respective cassettes 412.

The first transfer chamber 424 is part of a main frame 472 and houses a centrally disposed first transfer robot 432. The first transfer robot 432 is configured to move the patterned device structures between the loading dock 440 and a plurality of first processing chambers 460 (460a-d are shown in FIG. 4) and/or pass-through chambers 462. The first transfer chamber 424 can be selectively isolated from each of the first processing chambers 460 and pass-through chambers 462 by use of slit valves (not shown) that are disposed between each first processing chamber 460 and pass-through chamber 462 and the first transfer chamber 424.

Each loading dock 440 is selectively isolated from the first transfer chamber 424 by slit valves and from the interior region 416 of the factory interface 404 by vacuum doors (not shown). In this configuration, the factory interface robots 420 in the factory interface 404 are configured to move a patterned device structure from a cassette 412 to the loading dock 440, which may be sealed and pumped down to a desired pressure for transfer of the patterned device structure to the first transfer chamber 424. Upon reaching a desired pressure, the patterned device structure can then be accessed by the first transfer robot 432 through a slit valve opening (not shown) formed between the first transfer chamber 424 and the loading dock 440.

The first processing chambers 460 may include any suitable type of processing chambers for forming the passivation layer in the patterned device structures. In some embodiments, the first processing chambers 460 include one or more pre-clean chambers that are adapted to clean the surfaces of the patterned device structures. The pre-clean chambers may clean the surfaces of the patterned device structures by use of a cleaning process that includes exposing the surfaces of the patterned device structures to a radio frequency (RF) generated plasma and/or one or more pre-cleaning gas compositions that includes a carrier gas (e.g., Ar, He, Kr) and/or a reactive gas (e.g., hydrogen, oxygen, and/or water). In some embodiments, the pre-clean chambers are adapted to perform a non-ionizing H₂, O₂, and/or H₂O plasma pre-clean process that may minimize residual Si bonds on the dielectric layer, thereby forming a passivation layer on the dielectric layer, and minimizing damage to the dielectric layer.

The first transfer chamber 424 and the second transfer chamber 428 are coupled to each other via the pass-through chambers 462. In some configurations, the first transfer chamber 424 may be vacuum pumped to a moderately low pressure, for example, less than about 1 milliTorr (mTorr). The second transfer chamber 428 may be pumped to a lower pressure, for example, 1 microTorr or less. Accordingly, the first and second transfer chambers 424, 428 are maintained at least at a moderate vacuum level to prevent the transfer of contamination between the transfer chambers 424, 428 and other modules of the cluster tool 400.

Similar to the first transfer chamber 424, the second transfer chamber 428 is part of the main frame 472 and houses a centrally disposed second transfer robot 436. The second transfer robot 436 is configured to move the patterned device structures between each of a plurality of second processing chambers 470 and/or the pass-through chambers 462. The second transfer chamber 428 can be selectively isolated from each of the second processing chambers 470 and the pass-through chambers 462 by use of slit valves (not shown) that are disposed between each second processing chamber 470 and pass-through chamber 462 and the second transfer chamber 428. In certain embodiments, one or more of the second processing chambers 470 are ALD chambers configured to deposit metal gap fil materials as described herein.

### EXAMPLES

A remote plasma source and a remote direct plasma for the passivation layer deposition process was performed with varying treatment precursors. A reference treatment gas including only oxygen (reference) was compared to a treatment gas mixture including oxygen gas a hydrogen gas (example). The reference resulted in reduced dielectric passivation at temperatures of 100° C. to 400° C. compared to the example. The example resulted in dielectric passivation layer of greater than 1 nm at temperatures of 180° C. and dielectric passivation layer of greater than 1.2 nm at temperatures of 400° C. Additionally, the reference resulted in greater metal oxidation of the dielectric material and/or substrate at temperatures of 100° C. to 450° C. compared to the example. The example resulted in metal oxidation of less than 30 Å at temperatures of 100° C. to 450° C. Without being bound by theory, by forming a passivation layer using a remote plasma source and a remote direct plasma an increase of dielectric passivation may occur while maintaining lower metal oxidation of the exposed metal on the substrate 302 (e.g., metal material within the substrate), the upper dielectric material, and/or the lower dielectric material. A reduced metal oxidation can further reduce the resistivity within the contact structure, thereby enhancing device performance.

Overall, the processing systems 100, 400 and methods thereof, can allow for enhanced conformality of passivation layer formation, compared to conventional processing systems using a common plasma source, e.g., remote direct plasma source. Moreover, the increased conformality of the passivation layer can allow for enhanced dielectric passivation with minimal metal oxidation compared to conventional processing systems using a common plasma source. Thus, embodiments herein beneficially provide a relativity low-cost and high throughput, solution for conformal passivation layer formation, thereby reducing seams in the gap-fill material.

The term “coupled” is used herein to refer to the direct or indirect coupling between two objects. For example, if object A physically touches object B and object B touches object C, the objects A and C may still be considered coupled to one another-even if objects A and C do not directly physically touch each other. For instance, a first object may be coupled to a second object even though the first object is never directly in physical contact with the second object.

While the foregoing is directed to embodiments of the present disclosure, other and further embodiments of the disclosure may be devised without departing from the basic scope thereof, and the scope thereof is determined by the claims that follow.

What is claimed is:

1. A method of depositing a gap-fill material on a semiconductor substrate, comprising:
forming a passivation layer on a surface of a contact structure by introducing a hydrogen gas and an oxygen gas from a remote plasma source to a processing chamber, wherein:
the contact structure comprises a feature formed over a surface of the semiconductor substrate;
the feature comprises an opening that is defined by a surface of a substrate, a surface of a lower dielectric material disposed over the substrate, and a surface of an upper dielectric material disposed over the lower dielectric material; and
the passivation layer is formed over the surface of the substrate, the surface of the lower dielectric material, and the surface of the upper dielectric material; and
depositing a metal gap-fill material over a portion of the passivation layer to fill the feature formed in the surface of the semiconductor substrate.

2. The method of claim 1, wherein the hydrogen gas comprises hydrogen or water.

3. The method of claim 2, wherein the oxygen gas comprises oxygen or water.

4. The method of claim 3, wherein a ratio of the hydrogen gas to the oxygen gas is about 1 vol. % to about 100 vol. % of the hydrogen gas to the oxygen gas.

5. The method of claim 4, wherein the ratio of the hydrogen gas to the oxygen gas is about 1 vol. % to about 90 vol. % of the hydrogen gas to the oxygen gas.

6. The method of claim 4, wherein introducing the hydrogen gas and the oxygen gas from the remote plasma source to the processing chamber comprises introducing a treatment radical comprising a hydrogen radical, an oxygen radical, a hydroxide radical, or a combination thereof from the remote plasma source to the processing chamber.

7. The method of claim 6, wherein the treatment radical comprises the hydrogen radical.

8. The method of claim 6, wherein the treatment radical comprises the oxygen radical.

9. The method of claim 6, wherein the treatment radical comprises the hydroxide radical.

10. The method of claim 1, wherein forming the passivation layer on the surface of the contact structure comprises forming a thickness of about 10 Å to about 20 Å.

11. A method of depositing a gap-fill material on a semiconductor substrate, comprising:
performing a preclean process on a surface of a contact structure;
forming a passivation layer on the surface of the contact structure by introducing a first gas comprising hydrogen gas or an oxygen gas and a second gas comprising water from a remote plasma source to a processing chamber, wherein:
the contact structure comprises a feature formed in a surface of the semiconductor substrate;
the feature comprises an opening that is defined by a substrate, a lower dielectric material disposed over the substrate, and an upper dielectric material disposed over the lower dielectric material; and
the passivation layer is formed over the substrate, the lower dielectric material, and the upper dielectric material; and
depositing a metal gap-fill material over a portion of the passivation layer to fill the feature formed in the surface of the semiconductor substrate.

12. The method of claim 11, wherein the first gas comprises hydrogen gas.

13. The method of claim 11, wherein the first gas comprises oxygen gas.

14. The method of claim 11, wherein a ratio of the first gas to the second gas is about 1 vol. % to about 100 vol. % of the first gas to the second gas.

15. The method of claim 14, wherein the ratio of the first gas to the second gas is about 1 vol. % to about 90 vol. % of the first gas to the second gas.

16. The method of claim 14, wherein introducing the first gas and the second gas from the remote plasma source to the processing chamber comprises introducing a treatment radical comprising a hydrogen radical, an oxygen radical, a hydroxide radical, or a combination thereof from the remote plasma source to the processing chamber.

17. The method of claim 16, wherein the treatment radical comprises the hydrogen radical.

18. The method of claim 16, wherein the treatment radical comprises the oxygen radical.

19. The method of claim 16, wherein the treatment radical comprises the hydroxide radical.

20. The method of claim 11, wherein forming the passivation layer on the surface of the contact structure comprises forming a thickness of about 10 Å to about 20 Å.
